(19) United States
(12) Patent Application Publication
(10) Pub. No.: US 2025/0336445 A1
(43) Pub. Date: Oct. 30, 2025

(54) MEMORIES, OPERATION METHODS THEREOF, AND MEMORY SYSTEMS

(71) Applicant: YANGTZE MEMORY TECHNOLOGIES CO., LTD., Wuhan (CN)

(72) Inventors: Teng CHEN, Wuhan (CN); Weiwei HE, Wuhan (CN); Ke LIANG, Wuhan (CN)

(21) Appl. No.: 19/010,908

(22) Filed: Jan. 6, 2025

(30) Foreign Application Priority Data
Apr. 29, 2024 (CN) 202410545230.X

(51) Int. Cl. G11C 16/24; G11C 16/04

(52) U.S. Cl. CPC G11C 16/24; G11C 16/0483

(57) ABSTRACT

Examples of the present disclosure provide memories, operation methods thereof, and memory systems. A first discharge circuit in an example memory is able to discharge a bit line through a first discharge transistor based on a first voltage received. A second discharge circuit is able to discharge a source line through a second discharge transistor based on a second voltage received. The second voltage is higher than the first voltage, and a discharge current outputted by the second discharge transistor is greater than a discharge current outputted by the first discharge transistor.

### CROSS-REFERENCE TO RELATED APPLICATIONS

The present disclosure claims the benefit of priority to China Application No. 202410545230.X, filed on Apr. 29, 2024, the content of which is incorporated herein by reference in its entirety.

### TECHNICAL FIELD

The present disclosure relates to the technical field of memories, for example, memories, operation methods thereof, and memory systems.

### BACKGROUND

When an erase operation is performed on a memory block in a memory, a high erase voltage may be applied to a source line (SL) of the memory block. The high erase voltage can make a bottom select gate (BSG) connected with the SL generate a gate induced drain leakage (GIDL) current. The GIDL current will increase a potential of a channel in the memory block, so as to erase data stored in the memory block.

During the erase operation, the increasing of the potential of the channel may cause a bit line (BL) voltage to also be increased to the erase voltage. After the erase operation is completed, the BL and the SL may be discharged through a discharge circuit.

### SUMMARY

The present disclosure provides a memory, an operation method thereof, and a memory system.

A first aspect provides a memory. The memory may include a memory string and a peripheral circuit. The memory string may be connected between a bit line and a source line. The peripheral circuit may include a first discharge circuit connected with the bit line, and a second discharge circuit connected with the source line. The first discharge circuit includes a first discharge transistor, and the second discharge circuit includes a second discharge transistor. The first discharge circuit is configured to discharge the bit line through the first discharge transistor based on a first voltage received. The second discharge circuit is configured to discharge the source line through the second discharge transistor based on a second voltage received. The second voltage is higher than the first voltage, and a discharge current outputted by the second discharge transistor is greater than a discharge current outputted by the first discharge transistor.

In some examples, the first discharge circuit may further include a first switch transistor. A gate of the first switch transistor is configured to receive the first voltage. A first electrode of the first switch transistor is connected with the bit line. A second electrode of the first switch transistor is connected with a first electrode of the first discharge transistor. A gate of the first discharge transistor is configured to receive a third voltage. A second electrode of the first discharge transistor is configured to be grounded.

In some examples, the second discharge circuit further includes a second switch transistor. A gate of the second switch transistor is configured to receive the second voltage. A first electrode of the second switch transistor is connected with the source line. A second electrode of the second switch transistor is connected with a first electrode of the second discharge transistor. A gate of the second discharge transistor is configured to receive a third voltage. A second electrode of the second discharge transistor is configured to be grounded.

In some examples, the third voltage is equal to the first voltage.

In some examples, the first voltage ranges from 1.75 V to 2.2 V, and the second voltage ranges from 3 V to 3.6 V.

In some examples, both the switch transistors included in the first discharge circuit and the second discharge circuit are high voltage transistors.

In some examples, the first discharge transistor operates in a linear region, and the second discharge transistor operates in a saturation region.

In some examples, the peripheral circuit further includes a page buffer. All transistors in the first discharge circuit are transistors in the page buffer.

In some examples, the peripheral circuit further includes a current supply. One end of the current supply is respectively connected with the first discharge circuit and the second discharge circuit. The other end of the current supply is grounded. The current supply is configured to regulate the discharge current outputted to ground.

In some examples, all transistors included in the first discharge circuit and the second discharge circuit are N-type transistors.

A second aspect provides a method of operating a memory. The method includes providing a first voltage to a first discharge circuit in the memory such that a first discharge transistor in the first discharge circuit discharges a bit line; and providing a second voltage to a second discharge circuit in the memory such that a second discharge transistor in the second discharge circuit discharges a source line. The second voltage is higher than the first voltage, and a discharge current outputted by the second discharge transistor is greater than a discharge current outputted by the first discharge transistor.

In some examples, the providing the first voltage to the first discharge circuit in the memory includes providing the first voltage to a gate of a first switch transistor in the first discharge circuit such that the first switch transistor is turned on and provides a fourth voltage for a first electrode of the first discharge transistor. The method further includes providing a third voltage to a gate of the first discharge transistor such that the first discharge transistor discharges the bit line under the driving of the third voltage and the fourth voltage.

In some examples, the providing the second voltage to the second discharge circuit in the memory includes providing the second voltage to a gate of a second switch transistor in the second discharge circuit such that the second switch transistor is turned on and provides a fifth voltage for a first electrode of the second discharge transistor. The method further includes providing a third voltage to a gate of the second discharge transistor such that the second discharge transistor discharges the source line under the driving of the third voltage and the fifth voltage.

In some examples, the third voltage is equal to the first voltage.

In some examples, the first voltage ranges from 1.75 V to 2.2 V, and the second voltage ranges from 3 V to 3.6 V.

In some examples, the first discharge transistor operates in a linear region, and the second discharge transistor operates in a saturation region.

A third aspect provides a memory system. The memory system includes at least one memory as provided in the above-mentioned first aspect, and a controller coupled to the at least one memory and configured to control the at least one memory.

### BRIEF DESCRIPTION OF THE DRAWINGS

The drawings to be used in description of examples will be briefly introduced below in order to illustrate the technical solutions in the examples of the present disclosure more clearly. Apparently, the drawings described below are only some examples of the present disclosure. Those of ordinary skill in the art may obtain other drawings according to these drawings without creative work.

FIG. 1 is a schematic structural diagram of a memory provided by examples of the present disclosure.

FIG. 2 is a schematic cross-sectional view of a memory array provided by examples of the present disclosure.

FIG. 3 is a schematic structural diagram of another memory provided by examples of the present disclosure.

FIG. 4 is a schematic structural diagram of still another memory provided by examples of the present disclosure.

FIG. 5 is a schematic structural diagram of a discharge circuit in a peripheral circuit provided by examples of the present disclosure.

FIG. 6 is a schematic structural diagram of a current supply provided by examples of the present disclosure.

FIG. 7 is a schematic structural diagram of yet another memory provided by examples of the present disclosure.

FIG. 8 is a schematic structural diagram of a page buffer provided by examples of the present disclosure.

FIG. 9 is a schematic diagram of voltage variations in a source line and a bit line provided by examples of the present disclosure.

FIG. 10 is a schematic diagram of a voltage difference between a source line and a bit line provided by examples of the present disclosure.

FIG. 11 is a flow diagram of a method of operating a memory provided by examples of the present disclosure.

FIG. 12 is a schematic structural diagram of an electronic apparatus provided by examples of the present disclosure.

FIG. 13 is a schematic structural diagram of a memory card provided by examples of the present disclosure.

FIG. 14 is a schematic structural diagram of a solid state disk provided by examples of the present disclosure.

### DETAILED DESCRIPTION

Implementations of the present disclosure are further described in detail below with reference to the drawings.

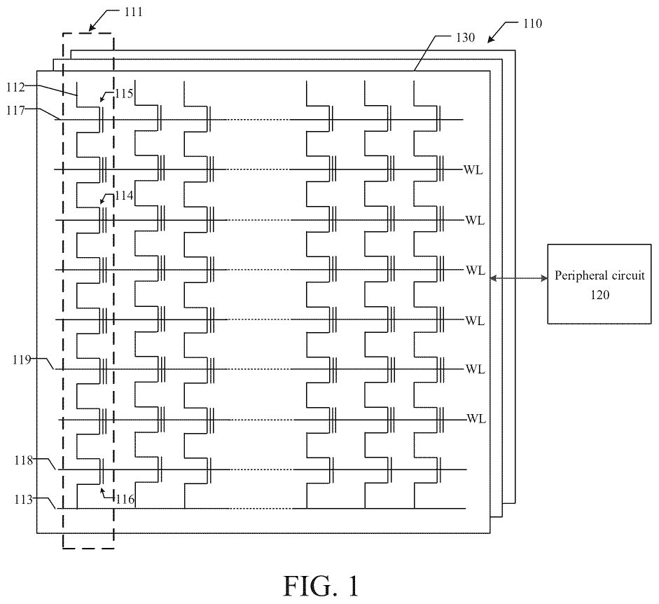

FIG. 1 is a schematic diagram of a memory provided by examples of the present disclosure. As shown in FIG. 1, the memory may include a memory array 110 including a plurality of memory strings 111. Each memory string 111 may include a plurality of memory cells 114 connected in series between a bit line 112 and a source line 113. The memory may include a peripheral circuit 120 coupled to the bit line 112 and the source line 113. The peripheral circuit 120 may be configured to perform a method of operating a memory provided by examples of the present disclosure.

The memory array 110 may be a NAND flash memory array. As shown in FIG. 1, the plurality of memory strings 111 included in the NAND flash memory array are arranged in an array on a substrate, and each memory strings 111 extends vertically above the substrate (not shown). For example, the plurality of memory cells 114 that are coupled in series and included in each memory strings 111 are vertically stacked above the substrate.

As shown in FIG. 1, each memory string 111 may further include a drain select gate (DSG) 115 on the top and a source select gate (SSG) 116 at the bottom. The drain select gate 115 is also referred to as a top select transistor, TSG, or a drain select transistor. The source select gate 116 is also referred to as a bottom select transistor, a bottom select gate (BSG), or a source select transistor. The source select gate 116 and the drain select gate 115 may be configured to activate a selected memory string 111 during read and program operations.

In some examples, the drain select gate 115 of each memory string 111 is coupled to a respective bit line 112, and data may be read or written from the bit line 112 via an output bus (not shown).

In some examples, each memory string 111 is configured to apply a select voltage (e.g., higher than a threshold voltage of a transistor having the drain select gate 115) or an unselect voltage (e.g., 0 V) to the respective drain select gate 115 via one or more DSG lines 117. In addition or alternatively, in some examples, each memory string 111 is configured to be selected or unselected by applying a select voltage (e.g., higher than a threshold voltage of a transistor having the source select gate 116) or an unselect voltage (e.g., 0 V) to the respective source select gate 116 via one or more SSG lines 118.

As shown in FIG. 1, the memory string 111 may be organized into a plurality of memory blocks 130; for any one of the plurality of memory blocks 130, the memory block 130 may have a source line (SL) 113; sources of all the memory strings 111 in the memory block 130 are coupled through the source line 113; and the source line 113 is also referred to as a common source line or an array common source (ACS).

The source line 113 may be configured to be grounded to achieve grounding of sources of various memory cells 114 of the memory string 111 of the memory block 130 in some subsequent operations. In an example, in some other operations, a high voltage may also be applied to the sources of various memory cells 114 of the memory string 111 of the memory block 130 through the source line 113.

Each memory block 130 is a basic data unit for an erase operation, e.g., all of the memory cells 114 on the same memory block 130 are erased at the same time. In order to erase the memory cells 114 in a selected memory block 130, the source line 113 coupled to the selected memory block may be biased with an erase voltage (Vers, such as a high positive voltage (20 V or higher)). It is to be understood that, in some other examples, the erase operation may be performed at a half block level, a quarter block level, or a level having any suitable number of blocks or any suitable fractions of a block.

As shown in FIG. 1, the memory cells 114 at a same layer of the adjacent memory strings 111 in the same memory block 130 may be coupled through word lines (WL) 119 that are configured to select which layer of memory cells 114 in the memory block 130 is affected by the read and program operations.

In some examples, each word line 119 is coupled to a page to which memory cells 114 belong, and a page is a basic data unit of the program operation. A size of the page may be related to the number of memory strings 111 coupled by the word line 119 in one memory block 130. Each word line 119 may be coupled to a control gate (e.g., a gate electrode) of each memory cell 114 in the respective page. It can be understood that, one memory cell row is the plurality of memory cells 114 located in the same page.

The plurality of word lines 119 are configured to perform operations such as programming (e.g., data writing), data reading, data erasing, etc. on a selected memory cell row among the plurality of memory cell rows, and the selected memory cell row is a memory cell row coupled with the selected word line.

In some examples, the memory cells 114 at the same layer in the same memory block 130 correspond to the same word line 119. In some examples, the memory cells 114 at the same layer may be divided into one or more pages. For example, one word line 119 may be coupled to one or more pages. For example, for a single level cell (SLC), one word line 119 is coupled to one page, and for a triple level cell (TLC), one word line 119 is coupled to three pages.

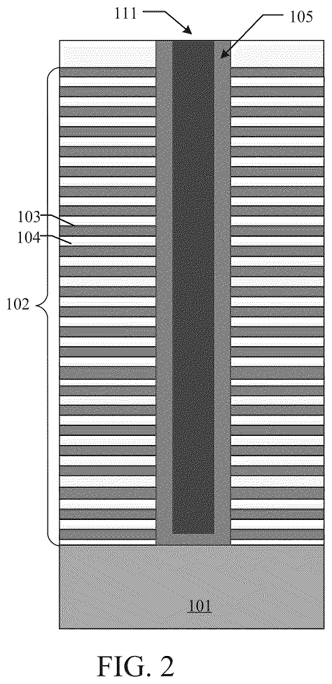

FIG. 2 is a schematic cross-sectional view of a memory array 110 including a memory string 111 provided by examples of the present disclosure. As shown in FIG. 2, the memory string 111 may extend vertically above a substrate 101 and run through a stacked layer 102. The substrate 101 may include silicon (e.g., single crystalline silicon), silicon germanium (SiGe), gallium arsenide (GaAs), germanium (Ge), silicon on insulator (SOI), germanium on insulator (GOI), or any other suitable materials.

The stacked layer 102 may include gate conductive layers 103 and gate-to-gate dielectric layers 104, which are alternate with each other. The number of pairs of the gate conductive layers 103 and the gate-to-gate dielectric layers 104 in the stacked layer 102 may determine the number of memory cells 114 in the memory array 110.

The gate conductive layer 103 may include a conductive material. The conductive material includes, but is not limited to, tungsten (W), cobalt (Co), copper (Cu), aluminum (Al), polysilicon, doped silicon, silicide, or any combination thereof. In some examples, each gate conductive layer 103 includes a metal layer, e.g., a tungsten layer. In some other examples, each gate conductive layer 103 includes a doped polysilicon layer. Furthermore, each gate conductive layer 103 may include a control gate surrounding a memory cell 114, and may horizontally extend at the top of the stacked layer 102 as a DSG line 117, horizontally extend at the bottom of the stacked layer 102 as an SSG line 118, or horizontally extend between the DSG line 117 and the SSG line 118 as the word line 119.

As shown in FIG. 2, the memory string 111 includes a channel structure 105 vertically extending and running through the stacked layer 102. In some examples, the channel structure 105 includes channel holes filled with (one or more) semiconductor materials (e.g., as semiconductor channels) and (one or more) dielectric materials (e.g., as memory films). The semiconductor channel includes silicon, e.g., polysilicon. The memory film is a composite dielectric layer including a tunneling layer, a storage layer (also referred to as a “charge trapping/storage layer”), and a blocking layer.

In some examples, the channel structure 105 has a cylindrical shape (e.g., a pillar shape). Various layers in the semiconductor channel and memory film are arranged radially from the center of a pillar toward an outer surface of the pillar in this order.

It is to be understood that, although not shown in FIG. 2, the memory array 110 may further include other additional components, and the additional components include, but are not limited to, gate line slits/source contacts, local contacts, interconnect layers, etc.

Referring back to FIG. 1, the peripheral circuit 120 may be coupled to the memory array 110 through the bit line 112, the word line 119, the source line 113, the SSG line 118, and the DSG line 117. The peripheral circuit 120 may include any suitable analog, digital, and hybrid signal circuits for promoting operations of the memory array 110 by applying and sensing at least one of voltage signals or current signals to and from the memory cell 114 via the bit line 112, the word line 119, the source line 113, the SSG line 118, and the DSG line 117.

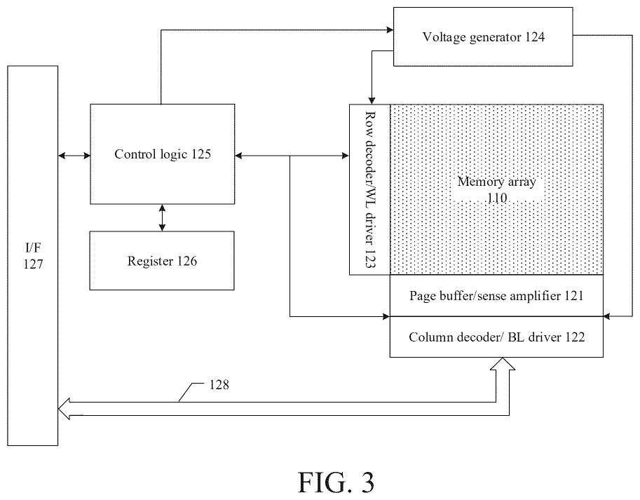

The peripheral circuit 120 may include various types of peripheral circuits formed using a metal-oxide-semiconductor (MOS) technology. For example, FIG. 3 shows some example peripheral circuits 120. The peripheral circuit 120 includes a page buffer/sense amplifier 121, a column decoder/bit line (BL) driver 122, a row decoder/WL driver 123, a voltage generator 124, a control logic 125, a register 126, an interface 127, and a data bus 128. It is to be understood that, in some examples, additional peripheral circuits not shown in FIG. 3 may also be included as well.

The page buffer/sense amplifier 121 may be configured to read and program (write) data from and to the memory array 110 according to a control signal from the control logic 125. For example, the page buffer/sense amplifier 121 may store one page of program data (write data) to be programmed into one page of the memory array 110. The page buffer/sense amplifier 121 may further perform a verify operation to ensure that the data has been properly programmed into the memory cell 114 coupled with the selected word line 119. The page buffer/sense amplifier 121 may further sense a low power signal from the bit line 112 that represents a data bit stored in the memory cell 114, and amplify a small voltage swing to a recognizable logic level in the read operation.

The column decoder/bit line driver 122 may be configured to be controlled by the control logic 125, and select one or more memory strings 111 by applying a bit line voltage generated from the voltage generator 124.

The row decoder/word line driver 123 may be configured to be controlled by the control logic 125, select/unselect the memory blocks 130 of the memory array 110, and select/unselect the word lines 119 of the memory blocks 130. The row decoder/word line driver 123 may further be configured to drive the word lines 119 using a word line voltage (VWL) generated from the voltage generator 124. In some examples, the row decoder/word line driver 123 may further select/unselect and drive the SSG line 118 and the DSG line 117. Moreover, the row decoder/word line driver 123 may further be configured to perform the erase operation on the memory cells 114 coupled to (one or more) selected word lines 119.

The voltage generator 124 may be configured to be controlled by the control logic 125, and generate the word line voltage (such as, a read voltage, a program voltage, a pass voltage, a local voltage, a verify voltage, etc.), the bit line voltage, a source line voltage, etc., which are to be supplied to the memory array 110.

The control logic 125 may be coupled to various circuits in the peripheral circuit 120 described above and configured to control operations of various circuits.

The register 126 may be coupled to the control logic 125 and include a state register, a command register, and an address register for storing state information, a command operation code (OP code), and a command address for controlling the operations of each circuit in the peripheral circuit 120.

The interface (I/F) 127 may be coupled to the control logic 125, and act as a control buffer to buffer and relay control commands received from a host (not shown) to the control logic 125 and state information received from the control logic 125 to the host. The interface 127 may also be coupled to the column decoder/bit line driver 122 via the data bus 128 and act as a data I/O interface and a data buffer to buffer and relay the data to and from the memory array 110.

When the erase operation is performed on a memory block 130, a negative voltage difference may be applied between the control gates of various memory cells 114 in the memory block 130 and a source terminal (e.g., the source line 113), so as to remove all trapped electronic charges in storage layers of various memory cells 114. For example, the control gates of the memory cells 114 may be configured to be grounded, and an erase voltage (Vers) is applied to the source line 113 to trigger the negative voltage difference.

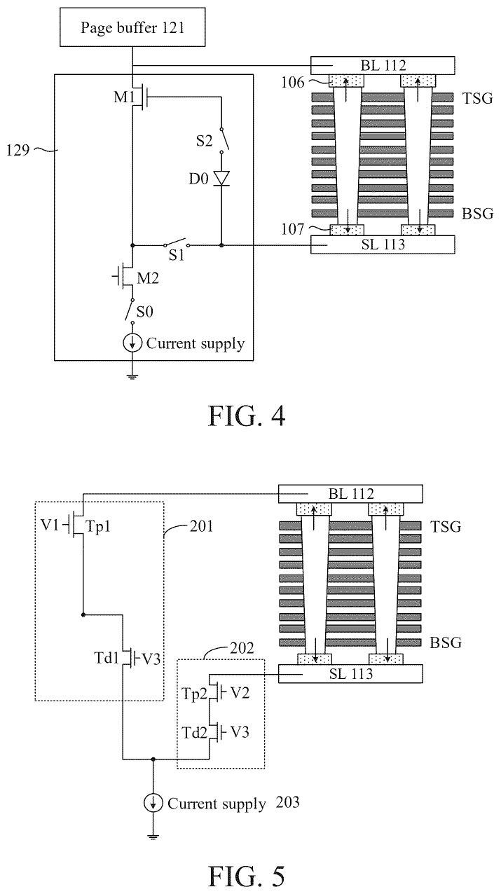

Referring to FIG. 4, the bit line (BL) 112 may be coupled to the semiconductor channel through a BL contact 106. The source line (SL) 113 may be coupled to the semiconductor channel through an SL contact 107. In some examples, the erase voltage is able to cause the source select gate 116 connected to the source line 113 to generate a GIDL current. The GIDL current is able inject charge carriers (e.g., holes) to the semiconductor channel. Therefore, a potential of the semiconductor channel may be raised to be close to or equal to the erase voltage applied to the source line 113. In this case, a negative voltage bias between the control gate of the memory cell 114 and the corresponding semiconductor channel may remove the charge carriers (e.g., electrons) trapped in the memory cell 114, and reduce the threshold voltage of the corresponding memory cell 114 accordingly.

Since the raising of the potential of the semiconductor channel may cause a potential of the bit line 112 to raise accordingly, after the erase operation ends, high potentials of the source line 113 and the bit line 112 may be discharged. In some examples, as shown in FIG. 4, the peripheral circuit 120 includes a discharge circuit 129; and the discharge circuit 129 may include transistors M1 and M2, switches S0 to S2, a diode D0, and a current supply. In a discharge process, the switches S0 to S2 are turned on, and the transistors M1 and M2 remain in an on state. Therefore, both the source line 113 and the bit line 112 may be grounded through the current supply, so as to discharge the source line 113 and the bit line 112.

Since the loading of the BL is less than the loading of the SL, the BL has a faster discharge rate. Therefore, a large voltage difference between the SL and the BL in the discharge process may be caused, and the large voltage difference affects the performance of the TSG connected with the BL. Furthermore, a plurality of transistors including the transistor M1 in the discharge circuit are all high voltage (HV) transistors, which are large in size and occupied area. In addition, the discharge circuit further includes the diode DO, resulting in a large size of the entire discharge circuit and high costs.

Examples of the present disclosure provide a memory. The discharge circuit in the memory is simple in circuit structure and small in occupied area, and the discharge circuit can guarantee a small voltage difference between the source line 113 and the bit line 112 in the discharge process, so as to avoid affecting the performance of the TSG. As shown in FIG. 1, the memory provided by the examples of the present disclosure includes the memory string 111 and the peripheral circuit 120. The memory string 111 is connected between the bit line 112 and the source line 113.

Referring to FIG. 5, the peripheral circuit 120 includes a first discharge circuit 201 connected with the bit line 112, and a second discharge circuit 202 connected with the source line 113. The first discharge circuit 201 includes a first discharge transistor Td1, and the second discharge circuit 202 includes a second discharge transistor Td2.

The first discharge circuit 201 is configured to discharge the bit line 112 through the first discharge transistor Td1 based on a first voltage V1 received.

The second discharge circuit 202 is configured to discharge the source line 113 through the second discharge transistor Td2 based on a second voltage V2 received.

The second voltage V2 is higher than the first voltage V1, and a discharge current outputted by the second discharge transistor Td2 is greater than a discharge current outputted by the first discharge transistor Td1.

In the examples of the present disclosure, since the second voltage V2 is higher than the first voltage V1, the discharge current outputted by the second discharge transistor Td2 is greater than the discharge current outputted by the first discharge transistor Td1, e.g., such that the source line 113 may have a higher discharge rate. Therefore, even if the loading of the bit line 112 is less than the loading of the source line 113, it may also ensure that the voltage difference between the source line 113 and the bit line 112 in the discharge process is not large. It can be understood that, if the voltage difference between the source line 113 and the bit line 112 in the discharge process is too large, the TSG generates a hot carrier injection (HCl) effect, leading to an offset in a threshold voltage of the TSG. Based on the solution provided by the examples of the present disclosure, the voltage difference between the source line 113 and the bit line 112 in the discharge process is small, such that the TSG may be prevented from generating an offset of the threshold voltage due to the HCl effect, thereby ensuring that the performance of the TSG is desirable.

To sum up, the examples of the present disclosure provide a memory. The first discharge circuit in the memory is able to discharge the bit line through the first discharge transistor based on the first voltage received. The second discharge circuit is able to discharge the source line through the second discharge transistor based on the second voltage received. The second voltage is higher than the first voltage, and the discharge current outputted by the second discharge transistor is greater than the discharge current outputted by the first discharge transistor. Because the discharge current when the second discharge circuit discharges the source line is large, a small voltage difference between the source line and the bit line during a discharge process can be guaranteed even if the loading of the source line is large, thereby avoid affecting the performance of a TSG connected with the bit line.

In an example, as shown in FIG. 5, the first discharge circuit 201 may further include a first switch transistor Tp1. A gate of the first switch transistor Tp1 is configured to receive the first voltage V1, a first electrode of the first switch transistor Tp1 is connected with the bit line 112, and a second electrode of the first switch transistor Tp1 is connected with a first electrode of the first discharge transistor Td1.

A gate of the first discharge transistor Td1 is configured to receive a third voltage V3, and a second electrode of the first discharge transistor Td1 is configured to be grounded. The third voltage V3 may also be less than the second voltage V2.

It can be understood that, the first switch transistor Tp1 is able to be turned on under the driving of the first voltage V1, and provide a fourth voltage for the first electrode of the first discharge transistor Td1. Since the first voltage V1 is lower than the second voltage V2, the fourth voltage received by the first electrode of the first discharge transistor Td1 may also be lower. Therefore, the discharge current outputted by the first discharge transistor Td1 may be small, so as to cause the bit line 112 to have a slow discharge rate.

In an example, continuously referring to FIG. 5, the second discharge circuit 202 may further include a second switch transistor Tp2. A gate of the second switch transistor Tp2 is configured to receive the second voltage V2, a first electrode of the second switch transistor Tp2 is connected with the source line 113, and a second electrode of the second switch transistor Tp2 is connected with a first electrode of the second discharge transistor Td2.

A gate of the second discharge transistor Td2 is configured to receive the third voltage V3, and a second electrode of the second discharge transistor Td2 is configured to be grounded.

It can be understood that, the second switch transistor Tp2 is able to be turned on under the driving of the second voltage V2, and provide a fifth voltage for the first electrode of the second discharge transistor Td2. Since the second voltage V2 is higher than the first voltage V1, the fifth voltage received by the first electrode of the second discharge transistor Td2 may also be high. Therefore, the discharge current outputted by the second discharge transistor Td2 may be large, so as to cause the source line 113 to have a fast discharge rate.

It can be understood that, in the examples of the present disclosure, one of the first electrode and second electrode of the transistor is a source, and the other one is drain. For example, the first electrode may be the source, and the second electrode may be the drain.

In an example, the first discharge transistor Td1 may be turned on under the driving of the third voltage V3 and the fourth voltage, and operate in a linear region. The second discharge transistor Td2 may be turned on under the driving of the third voltage V3 and the fifth voltage, and operate in a saturation region. Since an output current when the transistor operates in the saturation region is greater than an output current when the transistor operates in the linear region, it may ensure that the discharge current outputted by the second discharge transistor Td2 is greater than the discharge current outputted by the first discharge transistor Td1.

In the examples of the present disclosure, the third voltage V3 may be equal to the first voltage V1. Therefore, the complexity of driving the first discharge circuit 201 and the second discharge circuit 202 can be effectively reduced.

In an example, the first voltage V1 may range from 1.75 V to 2.2 V, and the second voltage V2 may range from 3 V to 3.6 V. In an example, the first voltage V1 may be 1.95 V, and the second voltage V2 may be 3.5 V or 3.6 V.

In an example, both the switch transistors (e.g., the first switch transistor Tp1 and the second switch transistor Tp2) included in the first discharge circuit 201 and the second discharge circuit 202 may be high voltage transistors. Furthermore, the two switch transistors may have same structures and sizes.

In an example, both the discharge transistors (e.g., the first discharge transistor Td1 and the second discharge transistor Td2) included in the first discharge circuit 201 and the second discharge circuit 202 may be common non-high voltage transistors. Furthermore, the two discharge transistors may have same structures and sizes.

In the examples of the present disclosure, all the transistors included in the first discharge circuit 201 and the second discharge circuit 202 may be N-type transistors. For example, the first switch transistor Tp1, the second switch transistor Tp2, the first discharge transistor Td1, and the second discharge transistor Td2 are all N-type transistors.

In an example, as shown in FIG. 5, the peripheral circuit 120 may further include the current supply 203. One end of the current supply 203 is respectively connected with the first discharge circuit 201 and the second discharge circuit 202, and the other end of the current supply 203 is grounded. The current supply 203 may be configured to regulate the discharge current outputted to ground.

From FIG. 5, it can be seen that, one end of the current supply 203 may be respectively connected with the second electrode of the first discharge transistor Td1 and the second electrode of the second discharge transistor Td2. For example, the second electrode of the first discharge transistor Td1 and the second electrode of the second discharge transistor Td2 may be grounded through the current supply 203. The discharge currents outputted by the two discharge transistors can flow to ground via the current supply 203.

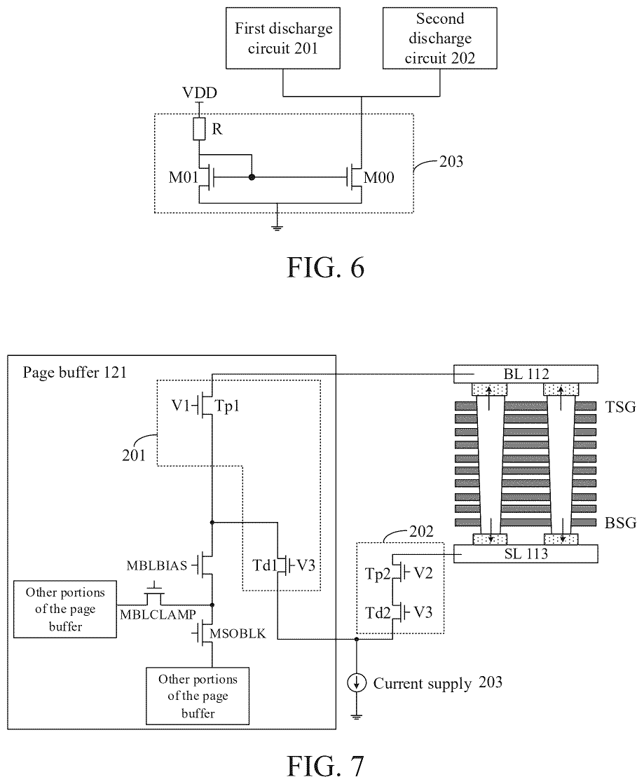

In the examples of the present disclosure, the current supply 203 may be a mirror current supply. FIG. 6 is a schematic structural diagram of a current supply provided by examples of the present disclosure. As shown in FIG. 6, the mirror current supply may include transistors M00 and M01, and a resistor R. One end of the resistor R is connected with a power terminal VDD, and the other end of the resistor R is respectively connected with a first electrode of the transistor M01, a gate of the transistor M01, and a gate of the transistor M00. A first electrode of the transistor M00 is respectively connected with the first discharge circuit 201 and the second discharge circuit 202. For example, the first electrode of the transistor M00 is respectively connected with the second electrode of the first discharge transistor Td1 and the second electrode of the second discharge transistor Td2. A second electrode of the transistor M00 and a second electrode of the transistor M01 are both grounded.

Based on an operating principle of the mirror current supply, it can be learned that the discharge currents outputted to the transistor M00 by the first discharge circuit 201 and the second discharge circuit 202 are equal to a current flowing through the resistor R. Therefore, the discharge currents outputted by the first discharge circuit 201 and the second discharge circuit 202 may be regulated by regulating a voltage of the power terminal VDD.

FIG. 7 is a schematic structural diagram of yet another memory provided by examples of the present disclosure. Referring to FIG. 7, the peripheral circuit 120 may further include a page buffer 121. Both the transistors (e.g., the first switch transistor Tp1 and the first discharge transistor Td1) in the first discharge circuit 201 may be transistors in the page buffer 121. An increase in an area occupied by the discharge circuit can be effectively avoided by reusing the transistors in the page buffer 121 to form the first discharge circuit 201, so as to avoid increasing an area of the peripheral circuit 120.

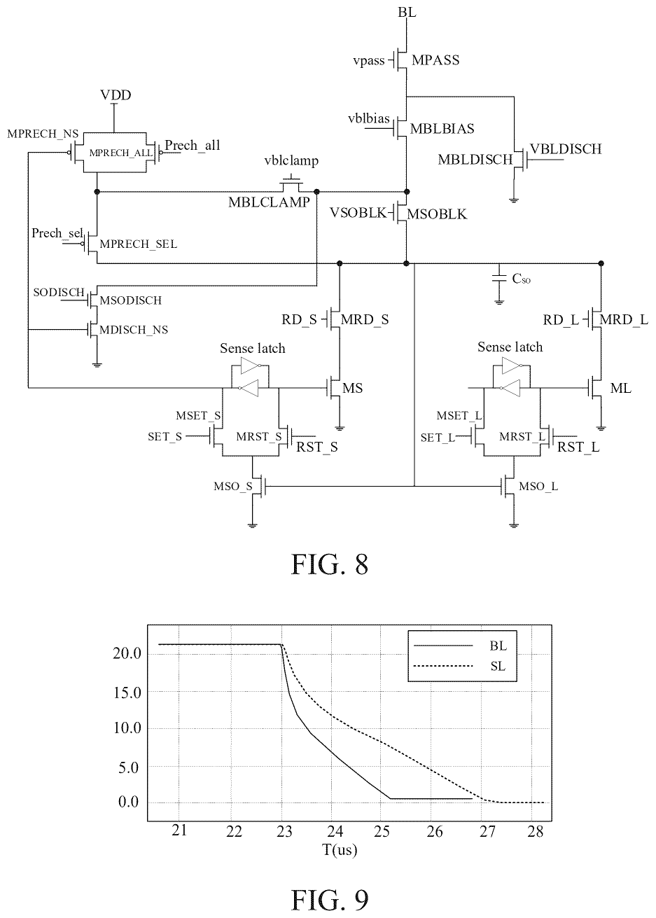

FIG. 8 is a schematic structural diagram of a page buffer provided by examples of the present disclosure. As shown in FIG. 8, the page buffer 121 may include the following transistors a transistor MPASS, a transistor MBLDISCH, a transistor MBLBIAS, a transistor MSOBLK, a transistor MBLCLAMP, a transistor MPRECH_NS, a transistor MPRECH_ALL, a transistor MPRECH_SEL, a transistor MSODISCH, a transistor MDISCH_NS, a transistor MRD_S, a transistor MS, a transistor MSET_S, a transistor MRST_S, a transistor MSO_S, a transistor MRD_L, a transistor ML, a transistor MSET_L, a transistor MRST_L, and a transistor MSO_L. Furthermore, the page buffer 121 may further include a capacitor CSO and two sense latches. Voltages received by gates of various transistors are also shown in FIG. 8. For example, the gate of the transistor MBLBIAS receives a voltage vblbias, the gate of the transistor MSOBLK receives a voltage VSOBLK, and the gate of the transistor MBLCLAMP receives a voltage vblclamp.

From FIG. 8, it can be seen that, a first electrode of the transistor MPASS is connected with the bit line 112. In the examples of the present disclosure, referring to FIGS. 7 and 8, the transistor MPASS may be reused as the first switch transistor Tp1. Furthermore, the transistor MBLDISCH may be reused as the first discharge transistor Td1.

It can be understood that, the reusing of the transistors does not affect normal operations (e.g., programming, reading, erasing, etc.) of the memory. For example, when the bit line 112 is charged through the page buffer 121, the first switch transistor Tp1 (e.g., the transistor MPASS) may be controlled to turn on, and the first discharge transistor Td1 (e.g., the transistor MBLDISCH) may be controlled to turn off.

Moreover, the first switch transistor Tp1 (e.g., the transistor MPASS) and the first discharge transistor Td1 (e.g., the transistor MBLDISCH) may also be configured to discharge the bit line 112 after the program or read operation. When the bit line 112 is discharged after the program or read operation, the first switch transistor Tp1 and the first discharge transistor Td1 may be controlled to turn on.

Based on the above-mentioned analysis, it can be learned that the first discharge circuit 201 in the memory provided by the examples of the present disclosure may reuse the transistors in the page buffer 121, such that an extra metal routing layer for discharging does not need to be added. Furthermore, the second discharge circuit 202 is simple in structure, and an extra diode does not need to be provided, such that an increase in the area of the peripheral circuit 120 in the memory may be effectively avoided, and the cost of the memory is reduced. For example, compared to the solution shown in FIG. 4, the solution of the examples of the present disclosure may save about 0.2 square millimeters (mm²) of an area per plane in the memory.

It can be understood that, each memory block 130 in the memory has one source line 113 and the plurality of bit lines 112. Accordingly, for each memory block 130, the peripheral circuit 120 may include the plurality of first discharge circuits 201 correspondingly connected with the plurality of bit lines 112 one by one, and the plurality of first discharge circuits 201 and one second discharge circuit 202 may be grounded through the current supply 203, and discharge through the current supply 203.

FIG. 9 is a schematic diagram of voltage variations in a source line and a bit line provided by examples of the present disclosure. A horizontal axis in FIG. 9 is time T, in microsecond (us); and a vertical axis is voltage, in V. From FIG. 9, it can be seen that, when T=23 us, various transistors included in the first discharge circuit 201 and the second discharge circuit 202 are turned on such that, after a discharge operation on the source line and the bit line is initiated, voltage of the source line and the bit line drop gradually. Furthermore, the drop in the voltage of the bit line is relatively fast.

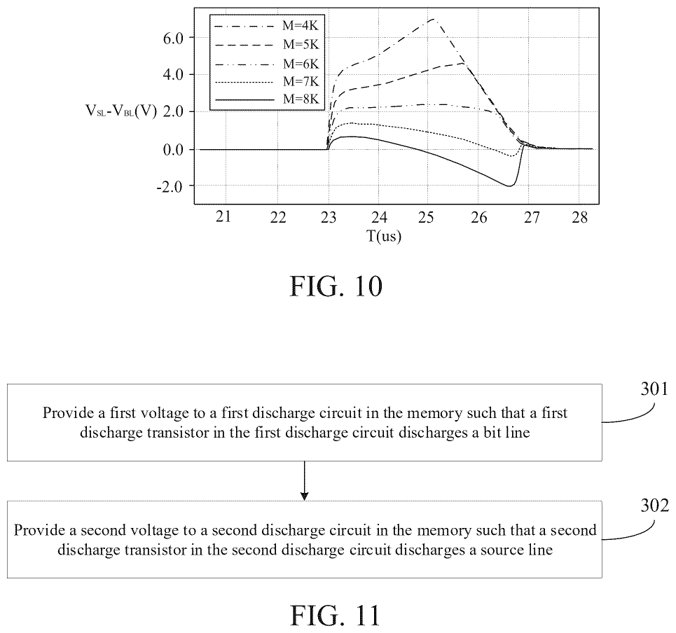

FIG. 10 is a schematic diagram of a voltage difference between a source line and a bit line provided by examples of the present disclosure, and FIG. 10 shows a voltage difference when multiplier (M) values of the second discharge transistor Td2 are different values. The M value of the second discharge transistor Td2 may refer to the number of MOS transistors connected in parallel, e.g., the number of the second discharge transistors Td2 connected in parallel in the second discharge circuit 202. For example, in FIG. 10, M=4 k may mean that there are 4 thousand (k) second discharge transistors Td2 connected in parallel in the second discharge circuit 202. A horizontal axis in FIG. 10 is time T, in us; and a vertical axis is a voltage difference between a voltage VSL of the source line and a voltage VBL of the bit line, e.g., VSL-VBL. The unit of the voltage difference is V.

From FIG. 10, it can be seen that, as the M value increases, the voltage difference between the source line and the bit line decreases gradually. For example, it can be learned, by sampling the voltage difference when T=25.096 us, that the voltage difference when M=4 k is 7.0166 V, the voltage difference when M=5 k is 4.3376 V, the voltage difference when M=6 k is 2.3416V, the voltage difference when M=7 k is 854.67 millivolts (mV), and the voltage difference when M=8 k is-297.7 mV. In the examples of the present disclosure, the M value of the second discharge transistor Td2 may be flexibly set according to requirements of an application scenario.

To sum up, the examples of the present disclosure provide a memory. The first discharge circuit in the memory is able to discharge the bit line through the first discharge transistor based on the first voltage received. The second discharge circuit is able to discharge the source line through the second discharge transistor based on the second voltage received. The second voltage is higher than the first voltage, and the discharge current outputted by the second discharge transistor is greater than the discharge current outputted by the first discharge transistor. Because the discharge current when the second discharge circuit discharges the source line is large, a small voltage difference between the source line and the bit line during a discharge process can be guaranteed even if the loading of the source line is large, thereby avoid affecting the performance of a TSG connected with the bit line.

Furthermore, the first discharge circuit in the memory provided by the examples of the present disclosure may reuse the transistors in the page buffer, and the second discharge circuit in the memory is simple in structure. Therefore, the structure of the peripheral circuit can be effectively simplified, the area of the peripheral circuit is decreased, and the cost of the memory is reduced.

FIG. 11 is a flow diagram of a method of operating a memory provided by examples of the present disclosure. The operation method may be applied to the memory as provided by the above-mentioned examples, and the method may be performed by the peripheral circuit in the memory. As shown in FIG. 11, the method includes as follows.

Operation 301, providing a first voltage to a first discharge circuit in the memory such that a first discharge transistor in the first discharge circuit discharges a bit line.

Operation 302, providing a second voltage to a second discharge circuit in the memory such that a second discharge transistor in the second discharge circuit discharges a source line.

The second voltage is higher than the first voltage, and a discharge current outputted by the second discharge transistor is greater than a discharge current outputted by the first discharge transistor.

In an example, in operation 301, providing the first voltage to the first discharge circuit in the memory may include providing the first voltage to a gate of a first switch transistor in the first discharge circuit such that the first switch transistor is turned on and provides a fourth voltage for a first electrode of the first discharge transistor.

The method may further include providing a third voltage to a gate of the first discharge transistor such that the first discharge transistor discharges the bit line under the driving of the third voltage and the fourth voltage.

In an example, in operation 302, providing the second voltage to the second discharge circuit in the memory may include providing the second voltage to a gate of a second switch transistor in the second discharge circuit such that the second switch transistor is turned on and provides a fifth voltage for a first electrode of the second discharge transistor.

The method may further include providing a third voltage to a gate of the second discharge transistor such that the second discharge transistor discharges the source line under the driving of the third voltage and the fifth voltage.

In an example, the third voltage may be equal to the first voltage. The first voltage may range from 1.75 V to 2.2 V, and the second voltage may range from 3 V to 3.6 V.

In an example, the first discharge transistor may be turned on under the driving of the third voltage and the fourth voltage, and operate in a linear region; and the second discharge transistor may be turned on under the driving of the third voltage and the fifth voltage, and operate in a saturation region.

It can be understood that, descriptions about the examples of the operation method of a memory have beneficial effects similar to those of the memory examples. Furthermore, technical details undisclosed in the examples of the operation method of a memory are understood with reference to descriptions about the memory examples.

To sum up, the examples of the present disclosure provide the operation method of a memory. The method is able to provide the first voltage for the first discharge circuit and provide the second voltage for the second discharge circuit such that the first discharge transistor discharges the bit line and the second discharge transistor discharges the source line. The second voltage is higher than the first voltage, and the discharge current outputted by the second discharge transistor is greater than the discharge current outputted by the first discharge transistor. Because the discharge current when the second discharge circuit discharges the source line is large, a small voltage difference between the source line and the bit line during a discharge process can be guaranteed even if the loading of the source line is large, thereby avoid affecting the performance of a TSG connected with the bit line.

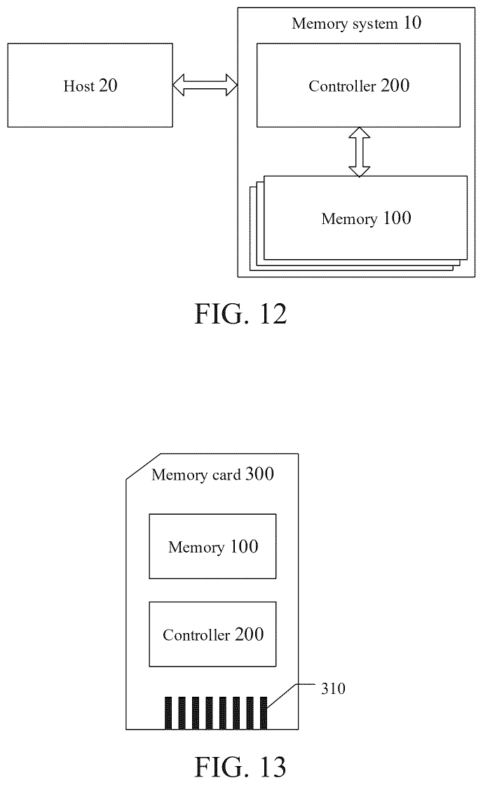

Examples of the present disclosure further provide a memory system. As shown in FIG. 12, the memory system 10 includes a controller 200 and at least one memory 100 provided by the above-mentioned examples. The controller 200 is coupled to the at least one memory 100 and configured to control the at least one memory 100.

In an example, FIG. 12 shows the plurality of memories 100. Each memory 100 may be a 3-dimension (3D) memory, for example, may be a 3D NAND flash memory. Each memory 100 may include at least one plane; each plane includes a plurality of memory blocks, and each memory block includes a plurality of memory pages. The controller 200 is respectively connected with the memory 100 and a host 20; and the controller 200 is configured to manage data stored in the memory 100, and communicate with the host 20.

In the examples of the present disclosure, the controller 200 may further be configured to control operations performed by the memory 100, such as read, erase, and program operations. The controller 200 may further be configured to manage various functions with respect to data stored or to be stored in the memory 100, including, but not limited to, bad block management, garbage collection (GC), logical-to-physical address translation, wear leveling, etc. In an example, the controller 200 may further be configured to process error correcting codes (ECC) with respect to the data read from or written to the memory 100. The controller 200 may further execute any other suitable functions, for example, formatting the memory 100.

The controller 200 may also communicate with an external apparatus according to a communication protocol. In an example, the controller 200 may communicate with the external apparatus through at least one of various interface protocols. The interface protocols may include a universal serial bus (USB) protocol, a multi-media card (MMC) protocol, a peripheral component interconnect (PCI) protocol, a PCI Express (PCI-E) protocol, an advanced technology attachment (ATA) protocol, a serial ATA protocol, a parallel ATA protocol, a small computer system interface (SCSI) protocol, an enhanced small drive interface (ESDI) protocol, an integrated drive electronics (IDE) protocol, a Firewire protocol, etc.

In some examples, the controller 200 and the one or more memories 100 may be integrated into various types of memory apparatuses.

As an example, as shown in FIG. 13, the controller 200 and the single memory 100 may be integrated into a memory card 300. The memory card 300 may include a personal computer memory card international association (PCMCIA) card, a compact flash (CF) card, a smart media (SM) card, a memory stick, a multi-media card (MMC), a secure digital (SD) card, a universal flash storage (UFS), etc. As shown in FIG. 13, the memory card 300 may further include a connector 310 for coupling with the host 20.

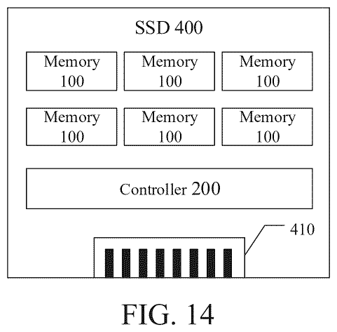

As another example, as shown in FIG. 14, the controller 200 and the plurality of memories 100 may be integrated into a solid state disk (SSD) 400. The solid state disk 400 may further include a connector 410 for coupling with the host 20. At least one of storage capacity or operation speed of the solid state disk 400 is greater than that of the memory card 300.

In addition, the memory 100 in FIG. 12 to FIG. 14 may be any memory involved in the examples of the present disclosure, for example, may be a 3D NAND (NAND gate) memory. The solutions provided in the examples of the present disclosure may be applied to an electronic apparatus. The electronic apparatus may include a mobile terminal, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having a memory.

Examples of the present disclosure further provide an electronic apparatus. As shown in FIG. 12, the electronic apparatus may include the memory system 10 as provided by the above-mentioned examples, and a host 20. The host 20 may be a central processing unit (CPU) or a system on chip (SoC) of the electronic apparatus. The host 20 is configured to send data to the memory system 10 for storage, or read data from the memory system 10.

In the present disclosure, the terms “first” and “second” are for descriptive purposes only, and cannot be construed as indicating or implying relative importance. The term “at least one” means one or more, and the term “a plurality of” means two or more, unless otherwise defined clearly.

The above descriptions are merely exemplary examples of the present disclosure, and are not intended to limit the present disclosure. The protection scope of the present disclosure shall be subject to the protection scope of the claims.

What is claimed is:

1. A memory, comprising:
a memory string connected between a bit line and a source line; and
a peripheral circuit comprising:
a first discharge circuit connected with the bit line and comprising a first discharge transistor; and
a second discharge circuit connected with the source line and comprising a second discharge transistor;
wherein:
the first discharge circuit is configured to discharge the bit line through the first discharge transistor based on a first voltage received;
the second discharge circuit is configured to discharge the source line through the second discharge transistor based on a second voltage received; and
the second voltage is higher than the first voltage, and a discharge current outputted by the second discharge transistor is greater than a discharge current outputted by the first discharge transistor.

2. The memory of claim 1, wherein the first discharge circuit further comprises a first switch transistor;
a gate of the first switch transistor is configured to receive the first voltage, a first electrode of the first switch transistor is connected with the bit line, and a second electrode of the first switch transistor is connected with a first electrode of the first discharge transistor; and
a gate of the first discharge transistor is configured to receive a third voltage, and a second electrode of the first discharge transistor is configured to be grounded.

3. The memory of claim 1, wherein the second discharge circuit further comprises a second switch transistor;
a gate of the second switch transistor is configured to receive the second voltage, a first electrode of the second switch transistor is connected with the source line, and a second electrode of the second switch transistor is connected with a first electrode of the second discharge transistor; and
a gate of the second discharge transistor is configured to receive a third voltage, and a second electrode of the second discharge transistor is configured to be grounded.

4. The memory of claim 2, wherein the third voltage is equal to the first voltage.

5. The memory of claim 4, wherein the first voltage ranges from 1.75 volts (V) to 2.2 V, and the second voltage ranges from 3 V to 3.6 V.

6. The memory of claim 2, wherein switch transistors comprised in the first discharge circuit and the second discharge circuit are high voltage transistors.

7. The memory of claim 1, wherein the first discharge transistor operates in a linear region, and the second discharge transistor operates in a saturation region.

8. The memory of claim 1, wherein the peripheral circuit further comprises a page buffer; and
transistors in the first discharge circuit are transistors in the page buffer.

9. The memory of claim 1, wherein the peripheral circuit further comprises a current supply, one end of the current supply being respectively connected with the first discharge circuit and the second discharge circuit, and the other end of the current supply being grounded; and
the current supply is configured to regulate the discharge current outputted to ground.

10. The memory of claim 1, wherein transistors comprised in the first discharge circuit and the second discharge circuit are N-type transistors.

11. A method of operating a memory, comprising:
providing a first voltage to a first discharge circuit in the memory such that a first discharge transistor in the first discharge circuit discharges a bit line; and
providing a second voltage to a second discharge circuit in the memory such that a second discharge transistor in the second discharge circuit discharges a source line,
wherein the second voltage is higher than the first voltage, and a discharge current outputted by the second discharge transistor is greater than a discharge current outputted by the first discharge transistor.

12. The method of claim 11, wherein the providing the first voltage to the first discharge circuit in the memory comprises:
providing the first voltage to a gate of a first switch transistor in the first discharge circuit such that the first switch transistor is turned on and provides a fourth voltage for a first electrode of the first discharge transistor, and
the method further comprises providing a third voltage to a gate of the first discharge transistor such that the first discharge transistor discharges the bit line under driving of the third voltage and the fourth voltage.

13. The method of claim 11, wherein the providing the second voltage to the second discharge circuit in the memory comprises:
providing the second voltage to a gate of a second switch transistor in the second discharge circuit such that the second switch transistor is turned on and provides a fifth voltage for a first electrode of the second discharge transistor, and
the method further comprises providing a third voltage to a gate of the second discharge transistor such that the second discharge transistor discharges the source line under driving of the third voltage and the fifth voltage.

14. The method of claim 12, wherein the third voltage is equal to the first voltage.

15. The method of claim 14, wherein the first voltage ranges from 1.75 V to 2.2 V, and the second voltage ranges from 3 V to 3.6 V.

16. The method of claim 11, wherein the first discharge transistor operates in a linear region, and the second discharge transistor operates in a saturation region.

17. A memory system, comprising:
at least one memory, each comprising:
a memory string connected between a bit line and a source line; and
a peripheral circuit comprising:
a first discharge circuit connected with the bit line and comprising a first discharge transistor, and
a second discharge circuit connected with the source line and comprising a second discharge transistor;
wherein:
the first discharge circuit is configured to discharge the bit line through the first discharge transistor based on a first voltage received;
the second discharge circuit is configured to discharge the source line through the second discharge transistor based on a second voltage received; and
the second voltage is higher than the first voltage, and a discharge current outputted by the second discharge transistor is greater than a discharge current outputted by the first discharge transistor; and
a controller coupled to the memory and configured to control the memory.

18. The memory system of claim 17, wherein the first discharge circuit further comprises a first switch transistor;
a gate of the first switch transistor is configured to receive the first voltage, a first electrode of the first switch transistor is connected with the bit line, and a second electrode of the first switch transistor is connected with a first electrode of the first discharge transistor; and
a gate of the first discharge transistor is configured to receive a third voltage, and a second electrode of the first discharge transistor is configured to be grounded.

19. The memory system of claim 17, wherein the second discharge circuit further comprises a second switch transistor;
a gate of the second switch transistor is configured to receive the second voltage, a first electrode of the second switch transistor is connected with the source line, and a second electrode of the second switch transistor is connected with a first electrode of the second discharge transistor; and
a gate of the second discharge transistor is configured to receive a third voltage, and a second electrode of the second discharge transistor is configured to be grounded.

20. The memory system of claim 17, wherein the first discharge transistor operates in a linear region, and the second discharge transistor operates in a saturation region.
